(19) United States
(12) Patent Application Publication
(10) Pub. No.: US 2026/0132543 A1
(43) Pub. Date: May 14, 2026

(54) METHOD FOR GROWING SINGLE CRYSTAL, METHOD FOR PRODUCING SEMICONDUCTOR SUBSTRATE, AND SEMICONDUCTOR SUBSTRATE

(71) Applicant: Novel Crystal Technology, Inc., Saitama (JP)

(72) Inventors: Yuki UEDA, Saitama (JP); Takuya IGARASHI, Saitama (JP); Kimiyoshi KOSHI, Saitama (JP)

(73) Assignee: Novel Crystal Technology, Inc., Saitama (JP)

(21) Appl. No.: 19/115,498

(22) PCT Filed: Aug. 7, 2023
(86) PCT No.: PCT/JP2023/028706

§ 371 Date: Mar. 26, 2025

(30) Foreign Application Priority Data
Sep. 29, 2022 (JP) 2022-156772

(51) Int. Cl. C30B 29/16; C01G 15/00; C30B 11/02; H10D 62/80

(52) U.S. Cl. CPC C30B 29/16; C01G 15/00; C30B 11/02; H10D 62/875; C01P 2002/52; C01P 2004/02; C01P 2006/40

(57) ABSTRACT

A single crystal growth method for growing a single crystal of a gallium oxide-based semiconductor, the method including growing the single crystal from a melt of a raw material of the single crystal in an oxidizing atmosphere. Density and average length of voids in the single crystal are controlled by a relative value of an Si concentration and an Sn concentration in the single crystal.

### TECHNICAL FIELD

The present invention relates to a method for growing a single crystal, a method for producing a semiconductor substrate, and a semiconductor substrate.

### BACKGROUND ART

A technique for growing a gallium oxide single crystal using the vertical Bridgman method (VB method) is known (see, e.g., PTL 1). In general, growth of single crystals of gallium oxide-based semiconductors by the vertical Bridgman method or the vertical gradient freeze (VGF) method is performed in an oxidizing atmosphere, e.g., to prevent damage to crucibles formed of a Pt-based material.

### CITATION LIST

### Patent Literature

PTL 1: JP 2020/164415 A

### SUMMARY OF INVENTION

### Technical Problem

In melt growth of gallium oxide-based semiconductors, the melt is easily decomposed into a Ga₂O gas and an O₂ gas, and voids are formed if these gases are incorporated into a growing crystal. There is also a case where bubbles are formed by oxygen that is expelled to the solid-liquid interface due to a difference in solubility limit of oxygen in the melt and in the crystal, and the bubbles are incorporated into a growing crystal and become voids. When devices are manufactured using the grown crystal of gallium oxide-based semiconductor, the voids may affect the device characteristics.

It is known that when growing, e.g., a crystal of sapphire which is classed as a high-melting-point oxide as are gallium oxide-based semiconductors, the density of voids in the crystal can be reduced by using a reducing gas. However, the growth of gallium oxide-based semiconductor crystals by the VB method, etc., needs to be performed in an oxidizing atmosphere as described above, hence, it is not possible to reduce the density of voids by means of a reducing gas.

It is an object of the invention to provide a single crystal growth method which is a method for growing a single crystal of a gallium oxide-based semiconductor in an oxygen atmosphere and which is capable of controlling a state of voids in the single crystal to suppress an effect on the characteristics of a device to be manufactured using the grown single crystal, a method for producing a semiconductor substrate using a single crystal grown by the growth method, and a semiconductor substrate produced by the producing method.

### Solution to Problem

To achieve the above-mentioned object, an aspect of the present invention provides a single crystal growth method, a method for producing a semiconductor substrate, and a semiconductor substrate defined below.
(1) A single crystal growth method for growing a single crystal of a gallium oxide-based semiconductor, the method comprising:
   growing the single crystal from a melt of a raw material of the single crystal in an oxidizing atmosphere,
   wherein density and average length of voids in the single crystal are controlled by a relative value of an Si concentration and an Sn concentration in the single crystal.
(2) The single crystal growth method defined in (1), wherein the density and average length of the voids are controlled respectively within ranges of 56 to 57000 cm⁻² and 14 to 85 μm by adjusting a value obtained by subtracting the Sn concentration from the Si concentration within a range of −2.8×10¹⁸ to 3.0×10¹⁸ cm⁻³.
(3) The single crystal growth method defined in (1), wherein the density and average length of the voids are controlled respectively within ranges of 56 to 57000 cm⁻² and 14 to 85 μm by adjusting the Si concentration to less than 4.0×10¹⁸ cm⁻³ and a value obtained by subtracting the Sn concentration from the Si concentration within a range of −2.8×10¹⁸ to 3.0×10¹⁸ cm⁻³.
(4) A semiconductor substrate producing method for producing a semiconductor substrate comprising a single crystal of a gallium oxide-based semiconductor, the method comprising:
   growing the single crystal from a melt of a raw material of the single crystal in an oxidizing atmosphere; and
   cutting the semiconductor substrate out of the single crystal,
   wherein density and average length of voids in the single crystal are controlled by a relative value of an Si concentration and an Sn concentration in the single crystal.
(5) The semiconductor substrate producing method defined in (4), wherein the average length of the voids is controlled according to thickness and plane orientation of the semiconductor substrate to suppress that the voids penetrate through between two main surfaces of the semiconductor substrate.
(6) The semiconductor substrate producing method defined in (4) or (5), wherein the density and average length of the voids are controlled respectively within ranges of 56 to 57000 cm⁻² and 14 to 85 μm by adjusting a value obtained by subtracting the Sn concentration from the Si concentration within a range of −2.8×10¹⁸ to 3.0×10¹⁸ cm⁻³.
(7) The semiconductor substrate producing method defined in (4) or (5), wherein the density and average length of the voids are controlled respectively within ranges of 56 to 57000 cm⁻² and 14 to 85 μm by adjusting the Si concentration to less than 4.0×10¹⁸ cm⁻³ and a value obtained by subtracting the Sn concentration from the Si concentration within a range of −2.8×10¹⁸ to 3.0×10¹⁸ cm⁻³.
(8) A semiconductor substrate, comprising:
   a single crystal of a gallium oxide-based semiconductor,
   wherein a value obtained by subtracting an Sn concentration from an Si concentration is in a range of −2.8×10¹⁸ to 3.0×10¹⁸ cm⁻³, and
   wherein the semiconductor substrate comprises voids with density and average length respectively within ranges of 56 to 57000 cm⁻² and 14 to 85 μm.
(9) The semiconductor substrate defined in (8), wherein the voids do not penetrate through between two main surfaces.
(10) The semiconductor substrate defined in (8) or (9), wherein the Si concentration is higher than 2×10¹⁷ cm⁻³ and the Sn concentration is higher than 2×10¹⁶ cm⁻³.

### Advantageous Effects of Invention

According to the invention, it is possible to provide a single crystal growth method which is a method for growing a single crystal of a gallium oxide-based semiconductor in an oxygen atmosphere and which is capable of controlling a state of voids in the single crystal to suppress an effect on the characteristics of a device to be manufactured using the grown single crystal, a method for producing a semiconductor substrate using a single crystal grown by the growth method, and a semiconductor substrate produced by the producing method.

### BRIEF DESCRIPTION OF DRAWINGS

FIG. 1 is a schematic vertical cross-sectional view showing a configuration of a single crystal growth apparatus used in the VB method.

FIG. 2 shows an image of a cross section of a semiconductor substrate having a (010) plane as a main surface in the present embodiment, as observed by an optical microscope.

FIG. 3 shows images of cross sections of four types of semiconductor substrates in the present embodiment, as observed by an optical microscope.

FIG. 4 is a graph showing a relationship between concentrations of Si and Sn as dopants and density of voids in semiconductor substrate.

FIG. 5 is a graph showing a relationship between concentrations of Si and Sn as dopants and average length of voids in semiconductor substrate.

FIG. 6 is a graph showing a relationship between density and average length of voids in semiconductor substrate.

### DESCRIPTION OF EMBODIMENTS

A single crystal growth method in an embodiment of the invention (hereinafter, referred to as the present growth method) is a method for growing a single crystal of a gallium oxide-based semiconductor and is a method which includes a step of growing the single crystal from a melt of a raw material of the single crystal in an oxidizing atmosphere and in which the density and average length of voids in the single crystal are controlled by a relative value of an Si concentration and an Sn concentration in the single crystal. The gallium oxide-based semiconductor here refers to β-Ga₂O₃, or refers to β-Ga₂O₃ including a substitutional impurity such as Al, In, or a dopant such as Sn, Si.

The present growth method uses a method for growing a single crystal of a gallium oxide-based semiconductor in an oxygen atmosphere, such as the vertical Bridgman method (VB method) or the vertical gradient freeze method (VGF method).

In these methods, the melt becomes Ga-rich (containing a high proportion of Ga) in a reducing atmosphere. Therefore, in case that a crucible formed of a Pt-based material such as PtRh or PtIr is used, alloying of the crucible with Ga may occur, lowering the melting point of the crucible and causing breakage of the crucible during growth and leakage of the melt.

In the present growth method, the single crystal is grown in an oxygen atmosphere, hence, use of a reducing gas during growth to reduce the void density as in the case of sapphire single crystals is not possible. Then, as a result of intensive research, the present inventors found that the density and average length of voids in a single crystal can be controlled by adjusting the relative values of the Si concentration and the Sn concentration in the single crystal. In the present growth method, this technique for controlling the density and length of voids in the single crystal is used to suppress an adverse effect of voids.

When a semiconductor substrate is cut out of a grown single crystal, having voids penetrating through between two main surfaces (between the front surface and the back surface) of the semiconductor substrate should be particularly avoided. A good quality epitaxial film cannot be deposited on a portion with voids penetrating through between the two main surfaces, and abnormal regions locally formed in the epitaxial film due to the voids become paths for leakage current. Meanwhile, the higher the density of voids in the single crystal, the greater the effect on the characteristics of a device manufactured using such a single crystal, hence, the density of voids in the single crystal is preferably low.

In the present growth method, by, e.g., adjusting a value obtained by subtracting the Sn concentration from the Si concentration in the single crystal within the range of −2.8×10¹⁸ to 3.0×10¹⁸ cm⁻³, it is possible to control the density and average length of voids in the single crystal respectively within the ranges of 56 to 57000 cm⁻² and 14 to 85 μm. In this regard, for example, preparation concentrations of Si and Sn in the raw material of the single crystal are adjusted respectively within the ranges of 0 to 0.03 atomic % and 0 to 0.1 atomic % relative to Ga so that the value obtained by subtracting the Sn concentration from the Si concentration in the single crystal is kept within the range of −2.8×10¹⁸ to 3.0×10¹⁸ cm⁻³.

Here, there is a tendency that the length of voids in the single crystal increases with a decrease in the density of voids, and conversely, the density of voids in the single crystal increases with a decrease in the length. Thus, the density and length of voids in the single crystal can be controlled so that, e.g., the density is as low as possible within a range in which voids have such a length that voids are unlikely to penetrate through between the two main surfaces of a semiconductor substrate cut out of the single crystal.

Voids formed in a single crystal of gallium oxide-based semiconductor are needle-shaped voids that extend in a direction of the crystal of gallium oxide-based semiconductor. Therefore, when a semiconductor substrate having a (010) plane as the main surface and a thickness in the direction is cut out of the single crystal, voids are most likely to penetrate through between the two main surfaces. In this case, by, e.g., controlling the average void length to be smaller than the thickness of the semiconductor substrate, it is possible to suppress that the voids penetrate through between the two main surfaces.

When a semiconductor substrate having a main surface largely inclined from the (010) plane is cut out of the single crystal, the inclination of the extending direction of voids from the thickness direction of the semiconductor substrate is larger, hence, the void length set to suppress penetration of voids through between the two main surfaces can be larger.

In this way, in the present growth method, by adjusting the relative values of the Si concentration and the Sn concentration in the single crystal, the average length of voids in the single crystal can be controlled according to the thickness and plane orientation of the semiconductor substrate to suppress that voids included in the semiconductor substrate penetrate through between the two main surfaces of the semiconductor substrate.

Next, a single crystal growth method using the VB method will be described as an example.

### (A Single Crystal Growth Apparatus)

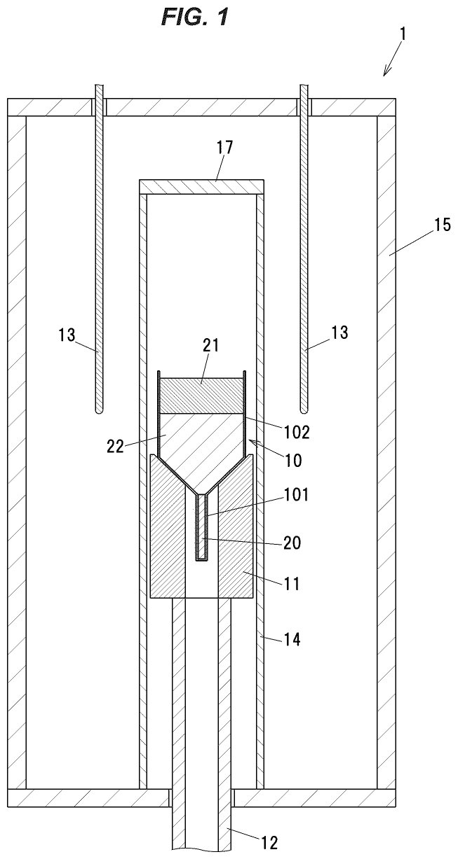

FIG. 1 is a schematic vertical cross-sectional view showing a configuration of a single crystal growth apparatus 1 used in the VB method. The single crystal growth apparatus 1 includes a crucible 10, a susceptor 11 that supports the crucible 10 from below and is movable vertically, a tubular furnace core tube 14 that surrounds the crucible 10, the susceptor 11 and a crucible support shaft 12, a heater 13 placed outside the furnace core tube 14, and a housing 15 that is formed of a thermal insulating material and accommodates these components of the single crystal growth apparatus 1.

The crucible 10 has a seed crystal section 101 to accommodate a seed crystal 20, and a growing crystal section 102 which is located on the upper side of the seed crystal section 101 and in which a single crystal 22 of gallium oxide-based semiconductor is grown by crystallizing a raw material melt 21 accommodated therein.

The growing crystal section 102 typically includes a constant diameter portion having a constant inner diameter larger than an inner diameter of the seed crystal section 101, and a diameter-increasing portion that is located between the constant diameter portion and the seed crystal section 101 and has an inner diameter increasing from the seed crystal section 101 side toward the constant diameter portion, as shown in FIG. 1.

The crucible 10 has a shape and size corresponding to a shape and size of the single crystal 22 to be grown. When growing, e.g., the single crystal 22 having a columnar-shaped constant diameter portion with a diameter of 2 inches, the crucible 10 provided with the growing crystal section 102 having a columnar-shaped constant diameter portion with an inner diameter of 2 inches is used. Meanwhile, when growing the single crystal 22 with the constant diameter portion having a shape other than the columnar shape, e.g., having a quadrangular prism shape or a hexagonal prism shape, the crucible 10 provided with the growing crystal section 102 having a quadrangular prism-shaped or hexagonal prism-shaped is used. A lid may be used to cover an opening of the crucible 10.

The crucible 10 is formed of a heat-resistant material capable of withstanding temperature of a gallium oxide-based semiconductor melt as the raw material melt 21 (temperature of not less than a melting point of the gallium oxide-based semiconductor) and less likely to react with the gallium oxide-based semiconductor melt, and is formed of, e.g., a PtRh alloy.

The susceptor 11 is a tubular member that surrounds the seed crystal section 101 of the crucible 10 and also supports the crucible 10 from below. The susceptor 11 is formed of a heat-resistant material capable of withstanding growth temperature of gallium oxide-based semiconductor single crystal and not reacting with the crucible 10 at the growth temperature, and is formed of, e.g., zirconia or alumina.

The crucible support shaft 12 is connected to the lower side of the susceptor 11, and the susceptor 11 and the crucible 10 supported by the susceptor 11 can be vertically moved by vertically moving the crucible support shaft 12 using a drive mechanism (not shown). The crucible support shaft 12 may also be able to be rotated about the vertical direction by the above-mentioned drive mechanism. In this case, the crucible 10 supported by the susceptor 11 can be rotated inside the furnace core tube 14.

The crucible support shaft 12 is typically a tubular member, in the similar manner to the susceptor 11. In this case, a thermocouple to measure temperature in the crucible 10 can be inserted inside the susceptor 11 and the crucible support shaft 12. The crucible support shaft 12 is formed of a heat-resistant material capable of withstanding growth temperature of gallium oxide-based semiconductor single crystal, and is formed of, e.g., zirconia or alumina.

The heater 13 is a heater to melt a raw material of gallium oxide-based semiconductor accommodated in the growing crystal section 102 to obtain the raw material melt 21. The heater 13 is inserted into the housing 15 from a hole provided on the housing 15 and is connected, outside of the housing 15, to an external device (not shown) to supply a current to the heater 13. The heater 13 is typically a MoSi₂ heater which is a resistive heating element formed of MoSi₂. The MoSi₂ heater is excellent in oxidation resistance and heat resistance, and can also be used in an oxidizing atmosphere at high temperatures of about 1800° C. which is required to grow gallium oxide-based semiconductor single crystals.

The furnace core tube 14 is used to regulate heat flow around the crucible 10 or to suppress contamination with impurities such as Si, Mo from the heater 13. The furnace core tube 14 typically has a circular tube shape. A lid 17 may be placed on an upper opening of the furnace core tube 14, as shown in FIG. 1. Upward escape of heat around the crucible 10 can be suppressed by using the lid 17. The furnace core tube 14 and the lid 17 are formed of a heat-resistant material capable of withstanding growth temperature of gallium oxide-based semiconductor single crystal, and is formed of, e.g., zirconia or alumina.

### (Single Crystal Growth Step)

First, the seed crystal 20 of gallium oxide-based semiconductor is placed in the seed crystal section 101 of the crucible 10, and a raw material of gallium oxide-based semiconductor single crystal is placed in the growing crystal section 102. Here, for example, the preparation concentrations of Si and Sn in the raw material of the single crystal are adjusted respectively within the ranges of 0 to 0.03 atomic % and 0 to 0.1 atomic % relative to Ga. As the raw material of the single crystal, it is possible to use, e.g., sintered Ga₂O₃ with Si or Sn added thereto, which is obtained by mixing SiO₂ powder or SiC powder as a Si source or SnO₂ powder as a Sn source with Ga₂O₃ powder and heating the mixture. Sintered Ga₂O₃, sintered SiO₂ or SiC, and sintered SnO₂ may also be used as the raw materials of the single crystal.

Next, the inside the single crystal growth apparatus 1 (the inner side of the housing 15) is heated by the heater 13 so as to form such a temperature gradient that temperature on the upper side is higher and temperature on the lower side is lower, thereby melting the raw material of the single crystal in the crucible 10 and obtaining the raw material melt 21.

In a typical method, first, the height of the crucible 10 is adjusted by vertically moving the crucible support shaft 12 so that temperature in an upper region in the growing crystal section 102 is increased to not less than the melting point of gallium oxide. An upper portion of the raw material inside the growing crystal section 102 is thereby melted. Next, the raw material is melted to the bottom while raising the crucible 10 at a predetermined speed by moving the crucible support shaft 12 upward at a predetermined speed, thereby eventually melting the entire raw material and a portion of the seed crystal.

Next, the raw material melt 21 is crystallized from the lower side (the seed crystal 20 side) while lowering the crucible 10 at a predetermined speed by moving the crucible support shaft 12 downward, thereby growing the single crystal 22. The single crystal growth described above is performed in an oxidizing atmosphere. After the entire raw material melt 21 is crystallized, the single crystal 22 is taken out of the crucible 10.

After that, the obtained single crystal 22 is sliced at desired intervals in a desired direction using a multi-wire saw, etc., and the surfaces are polished, thereby obtaining a semiconductor substrate having a desired thickness and a main surface with a desired plane orientation.

### (Evaluation Results)

Various evaluations were conducted on semiconductor substrates cut out of β-Ga₂O₃ single crystals obtained by the present growth method using the VB method (hereinafter, simply referred to as semiconductor substrates). The results are shown below.

Table 1 below shows the concentrations of Si and Sn included in the five types of semiconductor substrates made for this evaluation, and the preparation concentrations of Si and Sn in the raw materials of the single crystals from which the semiconductor substrates were cut out. “Preparation concentration of Si” and “Preparation concentration of Sn” in Table 1 are respectively the preparation concentration of Si and the preparation concentration of Sn in the single crystal raw materials. “Si—Sn concentration” means the Si concentration minus the Sn concentration. Then, “UID: Unintentional Doped” means no intentional doping with dopants.

TABLE 1

| | Preparation | Si | Preparation | Sn | Si—Sn |
|---|---|---|---|---|---|
| | concentration | concentration | concentration | concentration | concentration |
| Dopant | of Si (at %) | (cm⁻³) | of Sn (at %) | (cm⁻³) | (cm⁻³) |
| UID | 0 | 2 × 10¹⁷ | 0 | <2 × 10¹⁶ | 1.8 × 10¹⁷ to |
| | | | | | 2.0 × 10¹⁷ |
| Si | 0.03 | 2 × 10¹⁸ | 0 | <2 × 10¹⁶ | 2.0 × 10¹⁸ |
| | 0.03 | 3 × 10¹⁸ | 0 | <2 × 10¹⁶ | 3.0 × 10¹⁸ |
| Sn | 0 | 2 × 10¹⁷ | 0.1 | 3 × 10¹⁸ | −2.8 × 10¹⁸ |
| Si + Sn | 0.015 | 8 × 10¹⁷ | 0.1 | 3 × 10¹⁸ | −2.2 × 10¹⁸ |

In this evaluation, the concentrations of not intentionally added Si and Sn, which are the concentrations of Si and Sn inevitably mixed into the semiconductor substrates, were respectively 2×10¹⁷ cm⁻³ and not more than 2×10¹⁶ cm⁻³, as shown in Table 1.

Based on Table 1, the sample with a Si concentration of 2×10¹⁸ cm⁻³ and the sample with a Si concentration of 3×10¹⁸ cm⁻³ have the same preparation concentration of Si of 0.03 at %. This is because these two samples were cut out of regions with different Si concentrations in the same single crystal.

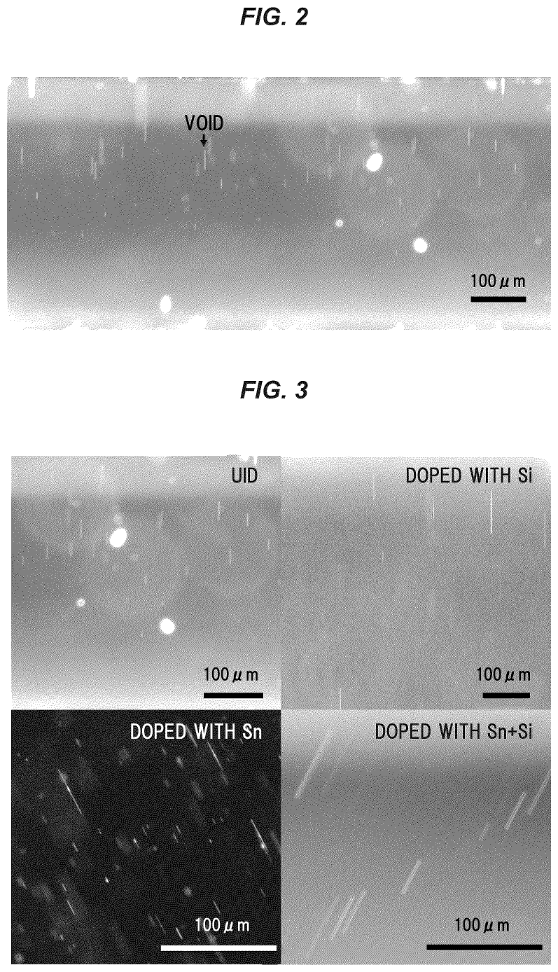

FIG. 2 shows an image of a cross section of a semiconductor substrate having a (010) plane as a main surface in the present embodiment, as observed by an optical microscope. The cross-section surface shown in FIG. 2 is the (100) plane, and the up-down direction of the image in FIG. 2 is the direction of the β-Ga₂O₃ single crystal. FIG. 2 shows that plural needle-shaped voids extending in the direction are included in the semiconductor substrate.

FIG. 3 shows images of cross sections of four types of semiconductor substrates in the present embodiment, as observed by an optical microscope. The observed image at top left is the same as the image shown in FIG. 2 and is an observed image showing a (100) cross-section surface of a semiconductor substrate which has the (010) plane as the main surface and is not intentionally doped with dopants. The observed image at top right is an observed image showing a (100) cross-section surface of a semiconductor substrate which has a (010) plane as the main surface and includes Si at a concentration of 3×10¹⁸ cm⁻³. The observed image at bottom left is an observed image showing a (100) cross-section surface of a semiconductor substrate which has a (011) plane as the main surface and includes Sn at a concentration of 3×10¹⁸ cm⁻³. The observed image at bottom right is an observed image showing a (100) cross-section surface of a semiconductor substrate which has a (011) plane as the main surface and includes Si at a concentration of 8×10¹⁷ cm⁻³ and Sn at a concentration of 3×10¹⁸ cm⁻³.

FIG. 3 shows that the density and size of voids in the semiconductor substrates vary depending on the type of dopant included in the semiconductor substrates, i.e., Si, Sn, or both Si and Sn.

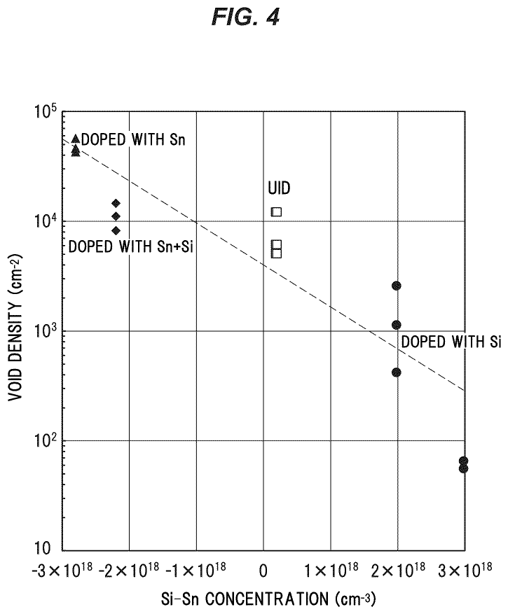

FIG. 4 is a graph showing a relationship between the concentrations of Si and Sn as dopants and the density of voids in semiconductor substrate. “Si—Sn concentration” on the horizontal axis in FIG. 4 means the Si concentration minus the Sn concentration. The density of voids in semiconductor substrate was calculated by counting the number of voids in a predetermined region of (100) cross-section surface. The area of the predetermined region is shown as “Observed area” in Table 2 below.

FIG. 4 shows that at least in the Si—Sn concentration range of −2.8×10¹⁸ to 3.0×10¹⁸ cm⁻³, the void density decreases as the Si concentration increases relative to the Sn concentration, and the void density increases as the Sn concentration increases relative to the Si concentration.

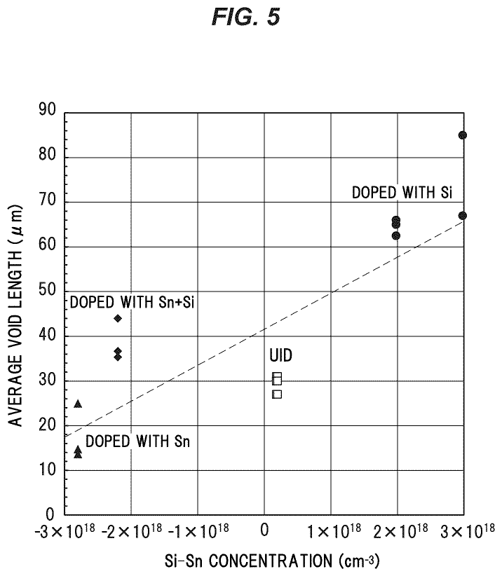

FIG. 5 is a graph showing a relationship between the concentrations of Si and Sn as dopants and the average length of voids in semiconductor substrate. “Si—Sn concentration” on the horizontal axis in FIG. 5 means the Si concentration minus the Sn concentration. The average length of voids in semiconductor substrate was obtained by measuring the lengths of voids in a predetermined region of (100) cross-section surface and averaging the measured values.

FIG. 5 shows that at least in the Si—Sn concentration range of −2.8×10¹⁸ to 3.0×10¹⁸ cm⁻³, the average void length increases as the Si concentration increases relative to the Sn concentration, and the average void length decreases as the Sn concentration increases relative to the Si concentration.

The Table 2 below shows “Si—Sn concentration” in the evaluated semiconductor substrates, the corresponding density and average length of voids, and the observed area of the cross sections of the semiconductor substrates and the number of voids observed, which were used to calculate the density and average length of voids.

TABLE 2

| | Si—Sn | | | | |
|---|---|---|---|---|---|
| | concentration | Observed area | Number of | Void density | Average void |
| Dopant | (cm⁻³) | (cm²) | voids | (cm⁻²) | length (μm) |
| UID | 1.8 × 10¹⁷ to | 4.6 × 10⁻³ | 56 | 1.2 × 10⁴ | 27 |
| | 2.0 × 10¹⁷ | | | | |
| | 1.8 × 10¹⁷ to | 6.7 × 10⁻³ | 34 | 5.1 × 10³ | 31 |
| | 2.0 × 10¹⁷ | | | | |
| | 1.8 × 10¹⁷ to | 6.5 × 10⁻³ | 40 | 6.1 × 10³ | 30 |
| | 2.0 × 10¹⁷ | | | | |
| Si | 2.0 × 10¹⁸ | 1.1 × 10⁻² | 29 | 2.6 × 10³ | 66 |
| | 2.0 × 10¹⁸ | 1.6 × 10⁻² | 18 | 1.1 × 10³ | 63 |
| | 2.0 × 10¹⁸ | 1.2 × 10⁻² | 5 | 4.2 × 10² | 65 |
| | 3.0 × 10¹⁸ | 1.5 × 10⁻² | 1 | 6.6 × 10 | 85 |
| | 3.0 × 10¹⁸ | 1.8 × 10⁻² | 1 | 5.6 × 10 | 67 |
| Sn | −2.8 × 10¹⁸ | 2.1 × 10⁻³ | 117 | 5.7 × 10⁴ | 15 |
| | −2.8 × 10¹⁸ | 2.7 × 10⁻³ | 116 | 4.3 × 10⁴ | 14 |
| | −2.8 × 10¹⁸ | 2.4 × 10⁻³ | 113 | 4.6 × 10⁴ | 25 |
| Si + Sn | −2.2 × 10¹⁸ | 2.4 × 10⁻³ | 20 | 8.2 × 10³ | 44 |
| | −2.2 × 10¹⁸ | 2.4 × 10⁻³ | 27 | 1.1 × 10⁴ | 35 |
| | −2.2 × 10¹⁸ | 2.9 × 10⁻³ | 42 | 1.5 × 10⁴ | 37 |

The results shown in FIGS. 4 and 5 indicate that the density and average length of voids included in a single crystal and a semiconductor substrate cut out therefrom can be controlled by the magnitude of the value obtained by subtracting the Sn concentration from the Si concentration. Meanwhile, the donor concentration in the single crystal and the semiconductor substrate depends on the total value of the Si concentration and the Sn concentration. Therefore, by intentionally doping with both Si and Sn, it is possible to control the density and average length of the voids while achieving the desired donor concentration. In this regard, when intentionally doping with both Si and Sn, the respective concentrations of Si and Sn are higher than the concentrations of unintentionally mixed Si and Sn and, for example, the Si concentration is higher than 2×10¹⁷ cm⁻³ and the Sn concentration is higher than 2×10¹⁶ cm⁻³. Specifically, the donor concentration in the single crystal and the semiconductor substrate is a value obtained by subtracting the concentration of Fe, which compensates the donor, from the sum of the Si concentration and the Sn concentration. This Fe is mixed into the single crystal from the crucible 10 and is present in the single crystal and the semiconductor substrate at a concentration of about not more than 1× 10¹⁷ cm⁻³.

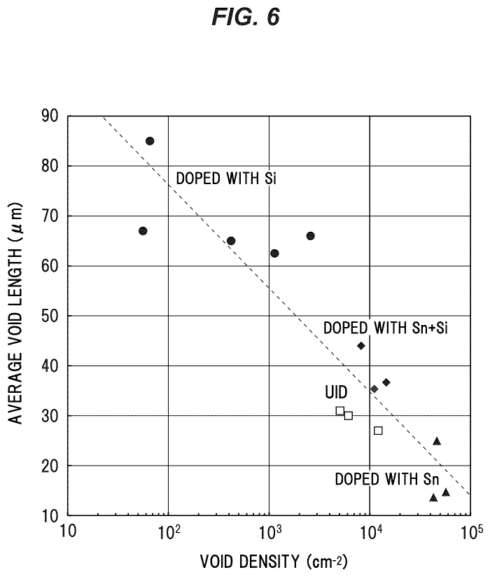

FIG. 6 is a graph showing a relationship between the density and the average length of voids in semiconductor substrate. FIG. 6 shows that at least in the range where the void density is 56 to 57000 cm⁻² and the average void length is 14 to 85 μm, the average void length increases as the void density decreases, and conversely, the void density increases as the average void length decreases.

The above evaluation results show that it is possible to produce a semiconductor substrate in which at least the value obtained by subtracting the Sn concentration from the Si concentration is in the range of −2.8×10¹⁸ to 3.0×10¹⁸ cm⁻³, and which includes voids with density and average length respectively in the ranges of 56 to 57000 cm⁻² and 14 to 85 μm. In addition, by controlling the average length of voids in the single crystal according to the thickness and plane orientation of the semiconductor substrate, it is possible to obtain a semiconductor substrate in which voids do not penetrate through between the two main surfaces.

It has been confirmed that when the Si concentration is not less than 4.0×10¹⁸ cm⁻³, huge void, which is considered to be a dense concentration of plural voids, tends to occur in the single crystal. Therefore, when the Si concentration is not less than 4.0×10¹⁸ cm⁻³, the relationship between the value obtained by subtracting the Sn concentration from the Si concentration and the void density and the relationship between the value obtained by subtracting the Sn concentration from the Si concentration and the average void length, which are described above, may not hold true. On the other hand, if the Si concentration is within the range shown in Table 1 (not more than 3.0×10¹⁸ cm⁻³), huge voids do not occur in the single crystal, and the relationship between the value obtained by subtracting the Sn concentration from the Si concentration and the void density and the relationship between the value obtained by subtracting the Sn concentration from the Si concentration and the average void length, which are described above, reliably hold true. Therefore, the Si concentration is preferably less than 4.0×10¹⁸ cm⁻³, more preferably, not more than 3.0×10¹⁸ cm⁻³.

The above evaluations were all conducted on the semiconductor substrates cut out of the single crystals of β-Ga₂O₃ which is a typical example of gallium oxide-based semiconductor, but similar results are obtained when the evaluations are conducted on semiconductor substrates cut out of single crystals of other gallium oxide-based semiconductors. Similar results are also obtained when the evaluations are conducted on semiconductor substrates cut of single crystals grown not by the VB method but by other methods in which single crystals are grown in an oxygen atmosphere, such as the VGF method.

### Effects of the Embodiment

According to the above-described embodiment of the invention, in a method in which a single crystal is grown in an oxygen atmosphere and the void density cannot be reduced by use of a reducing gas, the density and length of voids included in a gallium oxide-based semiconductor single crystal to be grown can be controlled and the effect of the voids on the characteristics of devices manufactured using semiconductor substrates, etc., cut out of the single crystal can be suppressed.

Although the embodiment of the invention has been described, the invention is not intended to be limited to the embodiment, and the various kinds of modifications can be implemented without departing from the gist of the invention. In addition, the constituent elements in the embodiment can be arbitrarily combined without departing from the gist of the invention. In addition, the invention according to claims is not to be limited to the embodiment described above. Further, it should be noted that not all combinations of the features described in the embodiment are necessary to solve the problem of the invention.

### INDUSTRIAL APPLICABILITY

Provided are a single crystal growth method which is a method for growing a single crystal of a gallium oxide-based semiconductor in an oxygen atmosphere and which is capable of controlling a state of voids in the single crystal to suppress an effect on the characteristics of a device to be manufactured using the grown single crystal, a method for producing a semiconductor substrate using a single crystal grown by the growth method, and a semiconductor substrate produced by the producing method.

### REFERENCE SIGNS LIST

1 SINGLE CRYSTAL GROWTH APPARATUS
10 CRUCIBLE
101 SEED CRYSTAL SECTION
102 GROWING CRYSTAL SECTION
11 SUSCEPTOR
13 HEATER
20 SEED CRYSTAL
21 RAW MATERIAL MELT
22 SINGLE CRYSTAL

1. A single crystal growth method for growing a single crystal of a gallium oxide-based semiconductor, the method comprising:
growing the single crystal from a melt of a raw material of the single crystal in an oxidizing atmosphere,
wherein density and average length of voids in the single crystal are controlled by a relative value of an Si concentration and an Sn concentration in the single crystal.

2. The single crystal growth method according to claim 1, wherein the density and average length of the voids are controlled respectively within ranges of 56 to 57000 cm⁻² and 14 to 85 μm by adjusting a value obtained by subtracting the Sn concentration from the Si concentration within a range of −2.8×10¹⁸ to 3.0×10¹⁸ cm⁻³.

3. The single crystal growth method according to claim 1, wherein the density and average length of the voids are controlled respectively within ranges of 56 to 57000 cm⁻² and 14 to 85 μm by adjusting the Si concentration to less than 4.0×10¹⁸ cm⁻³ and a value obtained by subtracting the Sn concentration from the Si concentration within a range of −2.8×10¹⁸ to 3.0×10¹⁸ cm⁻³.

4. A semiconductor substrate producing method for producing a semiconductor substrate comprising a single crystal of a gallium oxide-based semiconductor, the method comprising:
growing the single crystal from a melt of a raw material of the single crystal in an oxidizing atmosphere; and
cutting the semiconductor substrate out of the single crystal,
wherein density and average length of voids in the single crystal are controlled by a relative value of an Si concentration and an Sn concentration in the single crystal.

5. The semiconductor substrate producing method according to claim 4, wherein the average length of the voids is controlled according to thickness and plane orientation of the semiconductor substrate to suppress that the voids penetrate through between two main surfaces of the semiconductor substrate.

6. The semiconductor substrate producing method according to claim 4, wherein the density and average length of the voids are controlled respectively within ranges of 56 to 57000 cm⁻² and 14 to 85 μm by adjusting a value obtained by subtracting the Sn concentration from the Si concentration within a range of −2.8×10¹⁸ to 3.0×10¹⁸ cm⁻³.

7. The semiconductor substrate producing method according to claim 4, wherein the density and average length of the voids are controlled respectively within ranges of 56 to 57000 cm⁻² and 14 to 85 μm by adjusting the Si concentration to less than 4.0×10¹⁸ cm⁻³ and a value obtained by subtracting the Sn concentration from the Si concentration within a range of −2.8×10¹⁸ to 3.0×10¹⁸ cm⁻³.

8. A semiconductor substrate, comprising:
a single crystal of a gallium oxide-based semiconductor,
wherein the semiconductor substrate comprises voids with density and average length respectively within ranges of 56 to 57000 cm⁻² and 14 to 85 μm.

9. The semiconductor substrate according to claim 8, wherein a value obtained by subtracting an Sn concentration from an Si concentration is in a range of −2.8×10¹⁸ to 3.0×10¹⁸ cm⁻³.

10. The semiconductor substrate according to claim 8, wherein an Si concentration is less than 4.0×10¹⁸ cm⁻³ and a ratio of an Si concentration to an Sn concentration is in a range of 2×10¹⁷/3×10¹⁸ to 3×10¹⁸/2×10¹⁶.

11. The semiconductor substrate according to claim 8, wherein the voids do not penetrate through between two main surfaces.

12. The semiconductor substrate according to claim 9, wherein the voids do not penetrate through between two main surfaces.

13. The semiconductor substrate according to claim 10, wherein the voids do not penetrate through between two main surfaces.

14. The semiconductor substrate according to claim 8, wherein an Si concentration is higher than 2×10¹⁷ cm⁻³ and an Sn concentration is higher than 2×10¹⁶ cm⁻³.

15. The semiconductor substrate according to claim 9, wherein an Si concentration is higher than 2×10¹⁷ cm⁻³ and an Sn concentration is higher than 2×10¹⁶ cm⁻³.

16. The semiconductor substrate according to claim 10, wherein an Si concentration is higher than 2×10¹⁷ cm⁻³ and an Sn concentration is higher than 2×10¹⁶ cm⁻³.

17. The semiconductor substrate producing method according to claim 5, wherein the density and average length of the voids are controlled respectively within ranges of 56 to 57000 cm⁻² and 14 to 85 μm by adjusting a value obtained by subtracting the Sn concentration from the Si concentration within a range of −2.8×10¹⁸ to 3.0×10¹⁸ cm⁻³.

18. The semiconductor substrate producing method according to claim 5, wherein the density and average length of the voids are controlled respectively within ranges of 56 to 57000 cm⁻² and 14 to 85 μm by adjusting the Si concentration to less than 4.0×10¹⁸ cm⁻³ and a value obtained by subtracting the Sn concentration from the Si concentration within a range of −2.8×10¹⁸ to 3.0×10¹⁸ cm⁻³.
